(19) United States
(12) Patent Application Publication
(10) Pub. No.: US 2010/0084556 A1
(43) Pub. Date: Apr. 8, 2010

(54) OPTICAL-INFRARED COMPOSITE SENSOR AND METHOD OF FABRICATING THE SAME

(76) Inventors: Hyun-Hwa OH, Yongin-si (KR); II-Woong KWON, Daejeon-si (KR); Hee-Chul LEE, Daejeon-si (KR); Seong-Deok LEE, Suwon-si (KR); Yong-Soo LEE, Daejeon-si (KR); Won-Hee CHOE, Gyeongju-si (KR); Chi-Ho HWANG, Daejeon-si (KR); Hyuck-Jun SON, Seoul (KR)

Correspondence Address: North Star Intellectual Property Law, PC, P.O. Box 34688, Washington DC, DC, 20043, US

(21) Appl. No.: 12/563,423

(22) Filed: Sep. 21, 2009

(30) Foreign Application Priority Data
Oct. 7, 2008 (KR) 10-2008-0098410

(51) Int. Cl. H01L 31/02; H01L 21/50

(52) U.S. Cl. 250/338.4; 438/64; 257/E21.499

(57) ABSTRACT

Provided are an optical-infrared composite sensor and a method of fabricating the same. The optical-infrared composite sensor can sense both optical and infrared radiation. The optical-infrared composite sensor includes an infrared sensor formed on a substrate, a silicon cap enveloping the infrared sensor to vacuum-package the infrared sensor, and an optical sensor formed at one side of the silicon cap.

### CROSS REFERENCE TO RELATED APPLICATION(S)

This application claims the benefit under 35 U.S.C. §119(a) of a Korean Patent Application No. 10-2008-0098410, filed on Oct. 7, 2008, the disclosure of which is incorporated herein in its entirety by reference.

### BACKGROUND

1. Field

The following description relates to a sensor, and more particularly, to a composite sensor that senses visible and infrared radiation and a method of fabricating the composite sensor.

2. Description of Related Art

Optical sensors employing silicon are largely divided into two types: complementary metal-oxide semiconductor (CMOS) image sensors (CISs) and charge coupled devices (CCDs). Beyond the common feature that both types use a silicon photodiode, the difference between them can be seen in the signal acquisition method by which they process charge induced in the photodiode by absorption of visible light. The CCD employs a method of shifting charge, and the CIS employs a method of using a row or column decoder to read charge or charge converted into a voltage signal.

In order to acquire an image through visible light, a separate light source is needed. This is because ordinary objects don't emit light by themselves; they only reflect visible light coming from a light source such as the sun or fluorescent lighting. For this reason, information of visible light cannot be obtained in a dark environment. Just like people's eyes, ordinary optical sensors employing a photodiode also cannot obtain image information in a dark environment. In contrast, infrared sensors have the advantage of being able to obtain an image even without a separate light source. Infrared radiation is electromagnetic waves of a longer wavelength range than visible light, and all objects existing at normal temperatures emit infrared radiation by themselves. Infrared region signals cannot be sensed by people's eyes or optical sensors, however if an infrared sensor is employed, it becomes possible to see objects even in a dark environment.

For this reason, research about infrared sensors has been actively progressing over the past several decades. Infrared sensors largely include a photonic type which is also called a cooled type, and a thermal type which is also called an uncooled type. Photonic infrared sensors are based on the same principles as optical photodiodes employing silicon, only they have the difference of using a material with a narrower bandgap than silicon because infrared wavelengths are longer than visible wavelengths. In narrow bandgap materials, charges are excited by energy of ordinary temperature (300K), and thus photons generated by infrared radiation cannot be distinguished from photons generated by ordinary temperature. For this reason, photonic infrared sensors require a separate cooling device, and operate in a cooled state at an extremely low temperature of about 77K to prevent generation of photons by causes other than infrared radiation. In contrast, thermal infrared sensors have an appropriate structure for absorbing infrared radiation and sense infrared radiation by measuring change in electrical characteristics of the structure due to absorption of infrared radiation.

Optical sensors have high resolution based on considerably advanced technology. Also, because they have a small pixel area, they have a wide field of view and can obtain an image with clear edges. However, they still have the disadvantage of requiring a light source.

In contrast, while infrared sensors have the advantage of being able to see objects without a light source, they have the disadvantages of much lower resolution than optical sensors, narrow viewing angle due to relatively large pixel area, and obtaining an image in which an object's edges are unclear because they sense an infrared signal transferred by radiation from the object. The two kinds of images may be complementary; information about the heat from an object and the ability to ensure viewing even when there is no light source augment a high-resolution optical image.

### SUMMARY

According to one general aspect, there is provided an optical-infrared composite sensor including an infrared sensor formed on a substrate, a silicon cap formed to envelop the infrared sensor to vacuum-package the infrared sensor, and an optical sensor formed at one side of the silicon cap.

The infrared sensor may be a micro-bolometer.

The micro-bolometer may include an infrared responsive material, and the infrared responsive material may be vanadium oxide (VOx), amorphous silicon (a-Si), titanium (Ti), or a conductive organic material.

A gap to vacuum-package may be formed using, for example, a bulk micro-machining or surface micro-machining, at another side of the silicon cap and used to maintain a vacuum between the infrared sensor and the silicon cap.

The optical sensor may be a complementary metal-oxide semiconductor (CMOS) image sensor (CIS) or a charge-coupled device (CCD) sensor.

The optical-infrared composite sensor may further include a signal processing unit that receives and processes a signal from the infrared sensor or the optical sensor.

The signal processing unit may include a first signal processing unit integrated into the silicon cap and a second signal processing unit integrated into the substrate, wherein the first signal processing unit processes an optical signal and the second signal processing unit processes an optical-infrared signal.

The signal processing unit may be formed on the substrate and may process signals from the infrared sensor and the optical sensor to generate a composite image signal.

The signal processing unit may include an integrator to integrate input signals or a digital signal processor to merge an image.

The optical-infrared composite sensor may further include a joining part to physically connect the substrate and the silicon cap so that a vacuum is maintained, and a connection part to electrically connect the optical sensor and the infrared sensor.

The joining part may be made of PbSn or AuSn, and the connection part may be a bonding wire or a bump.

According to another aspect, there is provided a method of fabricating an optical-infrared composite sensor, the method including forming an infrared sensor on a substrate, preparing a silicon cap at one side of which an optical sensor is formed and at another side of which a gap is formed, and combining the silicon cap on the substrate so that the silicon cap envelops the infrared sensor and vacuum-packages the infrared sensor.

Other features and aspects will be apparent from the following detailed description, the drawings, and the claims.

### BRIEF DESCRIPTION OF THE DRAWINGS

FIG. 1 is a diagram illustrating an exemplary optical-infrared composite sensor.

FIG. 2 is a diagram illustrating a perspective view of an exemplary infrared sensor.

FIG. 3 is a diagram illustrating another exemplary optical-infrared composite sensor.

FIG. 4 is a diagram illustrating yet another exemplary optical-infrared composite sensor.

FIG. 5 is a flowchart showing an exemplary method of fabricating an optical-infrared composite sensor.

FIG. 6 is a block diagram illustrating an exemplary signal processing.

FIG. 7 is a block diagram illustrating another exemplary signal processing.

Throughout the drawings and the detailed description, unless otherwise described, the same drawing reference numerals will be understood to refer to the same elements, features, and structures. The relative size and depiction of these elements may be exaggerated for clarity, illustration, and convenience.

### DETAILED DESCRIPTION

The following detailed description is provided to assist the reader in gaining a comprehensive understanding of the methods, apparatuses, and/or systems described herein. Accordingly, various changes, modifications, and equivalents of the systems, apparatuses and/or methods described herein will be suggested to those of ordinary skill in the art. Also, descriptions of well-known functions and constructions may be omitted for increased clarity and conciseness.

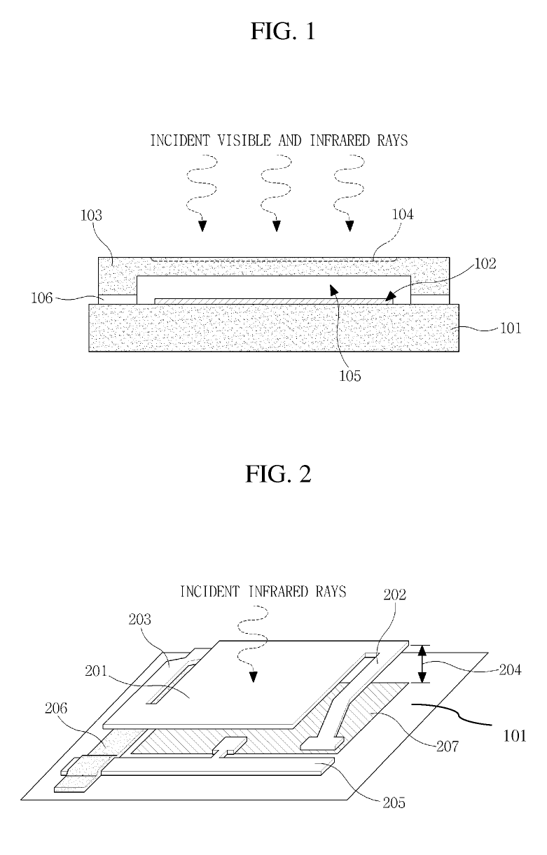

FIG. 1 illustrates the schematic structure of an exemplary optical-infrared composite sensor.

An exemplary optical-infrared composite sensor disclosed herein fabricated as, for example, a single chip may be used in the field of image information systems such as cameras.

While a conventional camera that can simultaneously see optical and infrared radiation has been developed, in such camera, an optical camera module for optical images and an infrared camera module for viewing infrared images are integrated on the system level. Since the two camera modules do not have the same field of view, a large amount of signal processing is needed to merge the two images.

Accordingly, an exemplary optical-infrared composite sensor is disclosed herein that has the same field of view for an optical sensor and an infrared sensor. Accordingly, when applied to a camera, signal processing and the resulting camera system may be simplified.

A camera system using an exemplary optical-infrared composite sensor disclosed herein may provide images regardless of the existence of a light source and may further provide information about the temperature of objects.

Referring to FIG. 1, an exemplary optical-infrared composite sensor includes a substrate 101, an infrared sensor 102, a silicon cap 103, and an optical sensor 104.

For example, a thermal infrared sensor may be used as the infrared sensor 102 formed on to the substrate 101 to sense incident infrared radiation.

Thermal infrared sensors may have an appropriate structure to absorb infrared radiation and sense infrared radiation by measuring change in electrical characteristics of the structure due to absorption of infrared radiation. For example, when the infrared sensor 102 converts temperature rise of a structure due to absorption of infrared radiation into an electrical signal, it may employ, for example, a bolometric method using change in resistance according to temperature rise, a pyroelectric method using a polarization phenomenon according to temperature rise, a thermopile method using variation of a built-in potential at a semiconductor or metal interface according to temperature, or other known or to be known methods. In the exemplary optical-infrared composite sensor of FIG. 1, the infrared sensor 102 may be implemented by a micro-bolometer employing a bolometric method.

The silicon cap 103 is formed to envelop the infrared sensor 102 to vacuum-package the infrared sensor 102. A gap 105 for vacuum-packaging may be formed in the silicon cap 103. For example, the gap 105 may be formed by processing a silicon wafer with a method such as a bulk micro-machining or surface machining. As another example, the silicon cap 103 may be physically connected to the substrate 101 with a joining part 106 so as to maintain vacuum inside the gap 105.

As shown in FIG. 1, the silicon cap 103 may include the optical sensor 104. For example, the optical sensor 104, such as a complementary metal-oxide semiconductor (CMOS) image sensor (CIS) or charge coupled device (CCD), may be integrated into one side of the silicon cap 103.

When light is incident on the optical-infrared composite sensor, visible light may be sensed by the optical sensor 104 formed in the silicon cap 103, and infrared radiation may be sensed by the infrared sensor 102 formed in the substrate 101. Also, the sensed radiation may be converted into an electrical signal and input to a signal processing unit (not shown). The signal processing unit may be formed on the substrate 101 and/or the silicon cap 103, or may be formed separately, and may process respective measurement signals of the sensors 102 and 104 to form an optical-infrared composite image.

FIG. 2 illustrates an exemplary infrared sensor. It may be one example of a micro-bolometer used as the infrared sensor 102 of FIG. 1.

Referring to FIG. 2, in the exemplary infrared sensor, a thin diaphragm 201 is formed spaced apart from the substrate 101 by a predetermined interval by two support bridges 202 and 203.

The diaphragm 201 may include an infrared absorber (not shown) and an infrared responder (not shown). When infrared radiation is incident on the diaphragm 201, the infrared radiation raises the temperature of the infrared absorber and the raised temperature changes the resistance of the infrared responder. That is, in response to absorption of infrared radiation, the temperature of the diaphragm 201 increases and its resistance may change. Such change in resistance can be sensed by measuring a current value of an X-lead 205 and a Y-lead 206 applying bias to the support bridges 202 and 203.

The diaphragm 201 and the substrate 101 are spaced apart by a resonance gap 204 therebetween. The resonance gap 204 may be set to a length of ¼ of an infrared wavelength to be absorbed. For example, in order to absorb infrared radiation of 10 μm wavelength, the resonance gap 204 may be 2-2.5 μm.

Also, a reflective panel 207 may be formed on one side of the substrate 101 corresponding to the diaphragm 201. Accordingly, electromagnetic waves of a specific wavelength range may resonate in the resonance gap 204 so that infrared radiation can be effectively absorbed.

The support bridges 202 and 203 may block heat between the diaphragm 201 and the substrate 101 and carry electrical current. While the diaphragm 201 may have a very small mass in order to maximize temperature rise caused by absorption of infrared radiation, the substrate 101 may have a relatively very large mass. Thus, the support bridges 202 and 203 are provided to thermally isolate the substrate 101 and the diaphragm 201, so as to prevent the temperature of the diaphragm 201 from being affected by the temperature of the substrate 101.

FIG. 3 illustrates another exemplary optical-infrared composite sensor.

Referring to FIG. 3, the exemplary optical-infrared composite sensor includes the substrate 101, the infrared sensor 102 formed on the substrate, the silicon cap 103 including the optical sensor 104, the joining part 106 to physically connect the substrate 101 and the silicon cap 103, a bonding wire 301 to electrically connect the optical sensor 104 and the infrared sensor 102, and signal processing units 401 and 402 that process signals of the sensors 102 and 104.

The micro-bolometer shown in FIG. 2 may be used as the infrared sensor 102 in FIG. 3. Here, vanadium oxide (VOₓ), amorphous silicon (a-Si), titanium (Ti), a conductive organic material, for example, may be used as an infrared responder of the infrared sensor 102.

The silicon cap 103 vacuum-packages the infrared sensor 102. The gap 105 is formed in one side of the silicon cap 103 to vacuum-package the infrared sensor 102. The optical sensor 104 which senses visible light is formed in another side of the silicon cap 103. Here, for example, a CIS sensor or a CCD sensor may be employed as the optical sensor 104.

The silicon cap 103 and the substrate 101 may be combined by the joining part 106 so as to maintain a vacuum inside the gap 105. As an example, PbSn using Au/Ni as a pad, or AuSn using Ti/Au as a pad, and the like may be used as the joining part 106.

Also as an example, the bonding wire 301 to electrically connect the optical sensor 104 and the infrared sensor 102 may be formed of a metal material such as Au or Al.

As shown in FIG. 3, the signal processing units 401 and 402 may be formed on the substrate 101 and the silicon cap 103, respectively. While not shown in FIG. 3, the signal processing units 401 and 402 may include a readout circuit to acquire electrical signals generated in the sensors 102 and 104, and a signal processing circuit to process the acquired signals and generate an image signal. Also, the signal processing circuit may include an integrator to integrate the acquired signals, an analog-to-digital converter (ADC) to convert analog signals into digital signals, and a digital signal processor to convert the acquired signals into an image signal.

As one example, a readout circuit to acquire an optical signal may be provided in the signal processing unit 402 formed in the silicon cap 103. Also, a readout circuit to acquire an infrared signal, and an optical-infrared signal processing circuit to process optical and infrared signals and generate a composite image signal, may be provided in the signal processing unit 401 formed on the substrate 101. While the optical-infrared signal processing circuit is described as being integrated into the signal processing unit 401 formed on the substrate 101, it is understood that the optical-infrared signal processing circuit may be provided separately.

With the signal processing units 401 and 402 shown in FIG. 3, the optical signal and the infrared signal are separately acquired and merged as further illustrated in FIG. 6.

In FIG. 6, the optical signal is sensed by an optical sensor, and is acquired by an optical signal acquisition circuit. The infrared signal is sensed by an infrared sensor, and is acquired by an infrared signal acquisition circuit. The separately acquired optical signal and infrared signal are processed by an optical-infrared signal processing circuit to output an optical-infrared image signal.

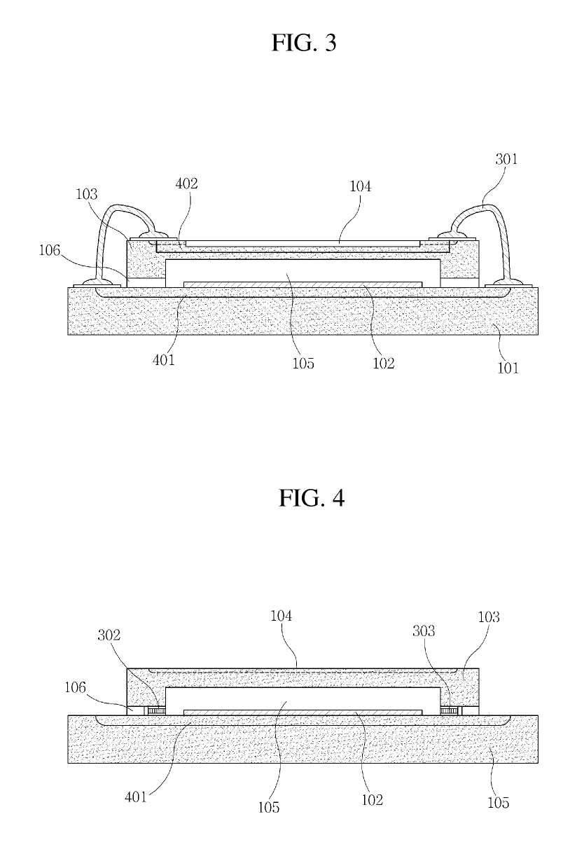

FIG. 4 illustrates yet another exemplary optical-infrared composite sensor according.

Referring to FIG. 4, the exemplary optical-infrared composite sensor includes the substrate 101, the infrared sensor 102 formed on the substrate, the silicon cap 103 including the optical sensor 104, the joining part 106 to physically connect the substrate 101 and the silicon cap 103, a bump 302 to electrically connect the optical sensor 104 and the infrared sensor 102, and the signal processing unit 401 to process signals of the sensors 102 and 104.

Again as an illustration, the micro-bolometer shown in FIG. 2 may be used as the infrared sensor 102 in FIG. 4. For example, vanadium oxide (VOₓ), amorphous silicon (a-Si), titanium (Ti), a conductive organic material, and the like may be used as an infrared responder of the infrared sensor 102.

The silicon cap 103 vacuum-packages the infrared sensor 102. The gap 105 to vacuum-package is formed in one side of the silicon cap 103. The optical sensor 104 which senses visible light is formed in another side of the silicon cap 103. As an example, a CIS sensor or a CCD sensor may be employed as the optical sensor 104.

The silicon cap 103 and the substrate 101 are combined by the joining part 106 so that the inside of the gap 105 is maintained in a vacuum. For example, PbSn using Au/Ni as a pad, or AuSn using Ti/Au as a pad, may be used as the joining part 106.

Also, the bump 302 electrically connecting the optical sensor 104 and the infrared sensor 102 may be formed using a material such as In, Au, PbSn, AuSn, and the like.

As shown in FIG. 4, the signal processing unit 401 may be formed on the substrate 101. While not shown in FIG. 4, the signal processing unit 401 may include a readout circuit to acquire electrical signals generated by the sensors 102 and 104, and a signal processing circuit to process the acquired signals and generate an image signal. Also, the signal processing circuit may include an integrator to integrate the acquired signals, an ADC to convert analog signals into digital signals, and a digital signal processor to convert the acquired signals into an image signal.

As one example, a readout circuit to acquire optical and infrared signals, and an optical-infrared signal processing circuit to process optical and infrared signals and generate a composite image signal, may be provided in the signal processing unit 401. Here, an electrode 303 for the optical-infrared signal processing circuit to read a signal from the optical sensor 104 may also be formed. It is understood that the optical-infrared signal processing circuit may be provided separately.

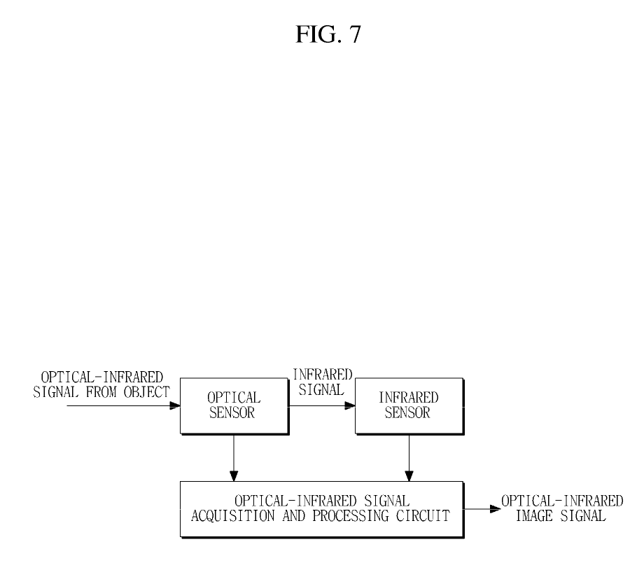

In this case, the optical signal and the infrared signal are acquired at the same time and merged as further illustrated in FIG. 7.

In FIG. 7, the optical signal is sensed by an optical sensor, and an infrared signal is sensed by an infrared sensor. Then, the sensed optical signal and infrared signal are simultaneously acquired and processed by an optical-infrared signal acquisition and processing circuit to output an optical-infrared image signal.

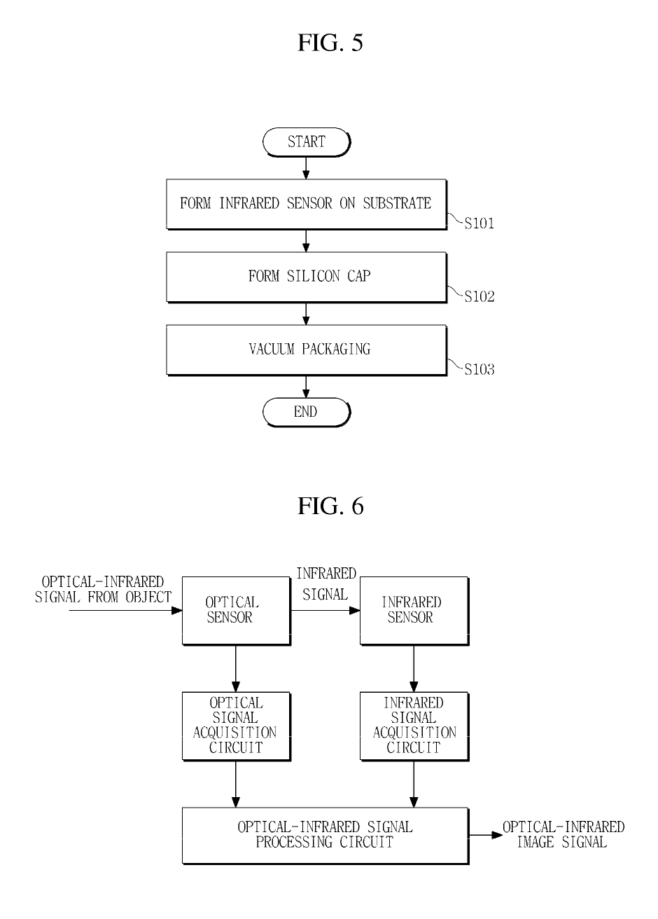

FIG. 5 is a flowchart showing a method of fabricating an exemplary optical-infrared composite sensor described above. In operation S101, an infrared sensor is formed on a substrate. For example, the above-described micro-bolometer may be formed on the substrate as the infrared sensor.

In operation S102, a silicon cap is provided. The silicon cap is provided to vacuum-package the infrared sensor, and a gap is formed on one side and an optical sensor is integrated into another side of the silicon cap. For example, a silicon wafer may be processed by a bulk micro-machining or surface micro-machining method to form the gap, and a CIS or CCD may be integrated into the opposite side to the gap to form the optical sensor.

In operation S103, the silicon cap is combined with the substrate to envelop the infrared sensor and the infrared sensor is vacuum-packaged.

A number of exemplary embodiments have been described above. Nevertheless, it will be understood that various modifications may be made. For example, suitable results may be achieved if the described techniques are performed in a different order and/or if components in a described system, architecture, device, or circuit are combined in a different manner and/or replaced or supplemented by other components or their equivalents. Accordingly, other implementations are within the scope of the following claims.

What is claimed is:

1. An optical-infrared composite sensor comprising:
an infrared sensor formed on a substrate;
a silicon cap enveloping the infrared sensor to vacuum-package the infrared sensor; and
an optical sensor formed at one side of the silicon cap.

2. The optical-infrared composite sensor according to claim 1, wherein the infrared sensor is a micro-bolometer.

3. The optical-infrared composite sensor according to claim 2, wherein the micro-bolometer includes an infrared responsive material, and the infrared responsive material is vanadium oxide (VOx), amorphous silicon (a-Si), titanium (Ti), or a conductive organic material.

4. The optical-infrared composite sensor according to claim 1, wherein a gap to vacuum-package is formed at another side of the silicon cap.

5. The optical-infrared composite sensor according to claim 4, wherein the gap is formed using a bulk micro-machining or surface micro-machining.

6. The optical-infrared composite sensor according to claim 1, wherein the optical sensor is a complementary metal-oxide semiconductor (CMOS) image sensor (CIS) or a charge-coupled device (CCD) sensor.

7. The optical-infrared composite sensor according to claim 1, further comprising:
a signal processing unit that receives and processes a signal from the infrared sensor or the optical sensor.

8. The optical-infrared composite sensor according to claim 7, wherein the signal processing unit includes a first signal processing unit integrated into the silicon cap and a second signal processing unit integrated into the substrate, and the first signal processing unit processes an optical signal and the second signal processing unit processes an optical-infrared signal.

9. The optical-infrared composite sensor according to claim 7, wherein the signal processing unit is formed on the substrate and processes signals from the infrared sensor and the optical sensor to generate a composite image signal.

10. The optical-infrared composite sensor according to claim 7, wherein the signal processing unit includes an integrator to integrate input signals or a digital signal processor to merge an image.

11. The optical-infrared composite sensor according to claim 1, further comprising:
a joining part to physically connect the substrate and the silicon cap so that a vacuum is maintained; and
a connection part to electrically connect the optical sensor and the infrared sensor.

12. The optical-infrared composite sensor according to claim 11, wherein the joining part is made of PbSn or AuSn.

13. The optical-infrared composite sensor according to claim 11, wherein the connection part is a bonding wire or a bump.

14. A method of fabricating an optical-infrared composite sensor, the method comprising:
forming an infrared sensor on a substrate;
forming a silicon cap having an optical sensor at one side thereof and a gap at another side thereof; and
combining the silicon cap on the substrate so that the silicon cap envelops the infrared to sensor to vacuum-package the infrared sensor.

15. The method according to claim 14, wherein the infrared sensor is a micro-bolometer.

16. The method according to claim 14, wherein the gap is formed using a bulk micro-machining or surface micro-machining.
